(19) United States
(12) Patent Application Publication
(10) Pub. No.: US 2003/0062609 A1
(43) Pub. Date: Apr. 3, 2003

(54) Identification of IC chip based on information formed on high-molecular film

(75) Inventor: Tsuyoshi Funatsu, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/252,386

(22) Filed: Sep. 24, 2002

(30) Foreign Application Priority Data
Oct. 3, 2001 (JP) 2001-307413

(51) Int. Cl. H01L 23/02

(52) U.S. Cl. 257/678

(57) ABSTRACT

A method is disclosed for easily identifying an IC chip. A high-molecular film is formed on the surface of an IC chip, and the color of the film is changed by irradiating the film with a laser beam of a specified wavelength range. A molecular structure in the high-molecular film is caused to change by a laser beam, which in turn changes the color of the film. This property is used to mark various data and to identify an IC chip with a difference in film color between an irradiation area and a non-irradiation area of the laser beam.

### BACKGROUND OF THE INVENTION

1. Field of the Invention

The present invention relates to a semiconductor device and a method for identifying the same as well as a system for manufacturing a semiconductor device.

2. Description of the Related Art

A method of identifying a semiconductor device is disclosed in Japanese Laid-Open Patent Publication No. 106960/92 as a conventional one. FIG. 1 is a top view showing the surface of the semiconductor device where a piece of information is recorded by the method as disclosed in this publication. As shown in FIG. 1, with this semiconductor device, the information of the semiconductor such as item name 11 (Dxxxx), lot No. 12 (9xxA01), 1 pin-mark 13 are indicated in certain IC chip unit area 10 formed by visual IC chip border line 9 on back side 8 of a pattern formed wafer.

In the method as disclosed in this publication, this information is recorded on each certain IC chip unit area 10 with a laser marking or the like at a time prior to a dicing process and at a time that is unlikely to affect other processes.

However, if this method is adopted, it is necessary to recognize a piece of information from the back side to confirm the information since the information of a semiconductor device is marked on back side 8. Accordingly, there arises a problem that a piece of marked information cannot be read out after an IC chip is assembled in a product.

A method of recording information of a semiconductor device from the front of an IC chip but not from a back side is also disclosed in Japanese Laid-Open Patent Publication No. 179849/82. FIG. 2 is a top view showing the surface of a semiconductor device where a piece of information is recorded by the method as disclosed in this publication. As shown in FIG. 2, with this semiconductor device, the maker's name 14 (AX -), product name 15 (Dxxxx) and mark 16 (55) comprising a figure, a character, a symbol or the like indicating its own array location are recorded in an area between scrive line 17 and chip layout area 18 in each IC chip pattern.

With this method, each pattern is later confirmed and a semiconductor device can be identified by a piece of recorded information such as a piece of information mentioned above. However, if this method is employed, it is necessary to provide the abovementioned area on an IC chip to write each item of information on an IC chip, there arises a problem that it is difficult to use this method as an IC chip has been increasingly miniaturized.

As mentioned above, writing a piece of information on the back side of an IC chip and the change of a layout to provide an area to write an item of information are conventionally performed on a semiconductor device in order to identify a semiconductor device.

However, if a marking is performed on the back side, there are problems that a piece of marked information cannot be read out after assembling and it is difficult to provide an area to write an item of information on each IC chip.

### SUMMARY OF THE INVENTION

It is an object of the present invention to provide a semiconductor device capable of easily identifying an IC chip without writing an item of information on the back side of an IC chip and the change of a layout in order to provide an area to write an item of information and a method of identifying the same as well as a system for manufacturing a semiconductor device.

According to one aspect of the present invention, a semiconductor device has a high-molecular film on the surface of a pattern formed IC chip which is irradiated with the light of a predetermined wavelength range to vary the color of the film.

The color of the high-molecular film varies with the irradiation of a laser beam in a specific wavelength range. The present invention utilizes this feature to enable an IC chip to be identified without the change of a layout in IC chips and writing of a piece of information on the back side of an IC chip.

The present invention provides the following advantages in identifying a semiconductor IC.

1) After confirming the electric characteristics at the time of P/W (pellet by wafer), the color of a high-molecular film is changed by irradiating a predetermined surface of an IC chip to thereby record data on the identification of a high-speed derivative product and criteria of passing/rejection thereof.

2) The change of a film color alone makes it possible to easily identify a piece of information (P/W data or the like) in a previous process visually and to recognize P/W condition at the time of pellet shipment.

3) Since the use of a laser beam to record a piece of information on an IC chip can increase the resolution of recorded information in place of ink that has been conventionally used, a piece of information to be recorded on an IC chip can be increased. A piece of information is recorded on an IC chip by irradiating a high-molecular film. The identification of an IC chip is facilitated since a piece of information can be recorded without writing on the back side of an IC chip and layout change.

Another semiconductor device according to the present invention has a protective film formed between an IC chip and a high-molecular film and a wavelength range that allows a molecular bond constituting the protective film to be dissociated is shorter than that of a predetermined wavelength range.

A high-molecular film is preferably made of Aberchrome 540 or of Aberchrome 850.

In addition, according to another aspect of the present invention, a method of identifying a plurality of IC chips obtained from a pattern formed wafer, comprises the steps of;

forming a high-molecular film on the surface of an IC chip, the color of which is changed by irradiating thereon with the light of a predetermined wavelength range,

recording a piece of information on each IC chip by irradiating the high-molecular film, and

identifying each IC chip based on information recorded on the high-molecular film.

According to another aspect of the present invention, a system for manufacturing of a semiconductor device comprises means for forming a high-molecular film on the surface of an IC chip, the color of the film being changed by irradiating the film with the light of a predetermined wavelength range, and light irradiating means for irradiating said IC chip.

According to an embodiment of the present invention, the manufacturing system is further provided with a slit which is interposed between the light irradiating means and the semiconductor device and limits the area of a light reaching an IC chip to a predetermined shape.

The use of a slit allows only the color of an arbitrary position in a high-molecular film to be changed, thereby forming a bar code, a character, a numeric, a symbol or the like on a high-molecular film by controlling the shape of a slit as desired.

The above and other objects, features and advantages of the present invention will become apparent from the following description with reference to the accompanying drawings which illustrate examples of the present invention.

### BRIEF EXPLANATION OF THE DRAWINGS

FIG. 1 is a top view showing the surface of a semiconductor device where a piece of information is recorded by the method as disclosed in Japanese Laid-Open Patent Publication No.04-1066960;

FIG. 2 is a top view showing the surface of a semiconductor device where a piece of information is recorded by the method as disclosed in Japanese Laid-Open Patent Publication No.57-179849;

FIG. 3 is a cross section showing a semiconductor device of one embodiment according to the present invention and the constitution of a manufacturing system of a semiconductor device;

FIG. 4 is a view showing the molecular structures of Aberchrome 540 and Aberchrome 850 and changes in their film colors;

FIG. 5 is a cross section showing the structure of an IC package.

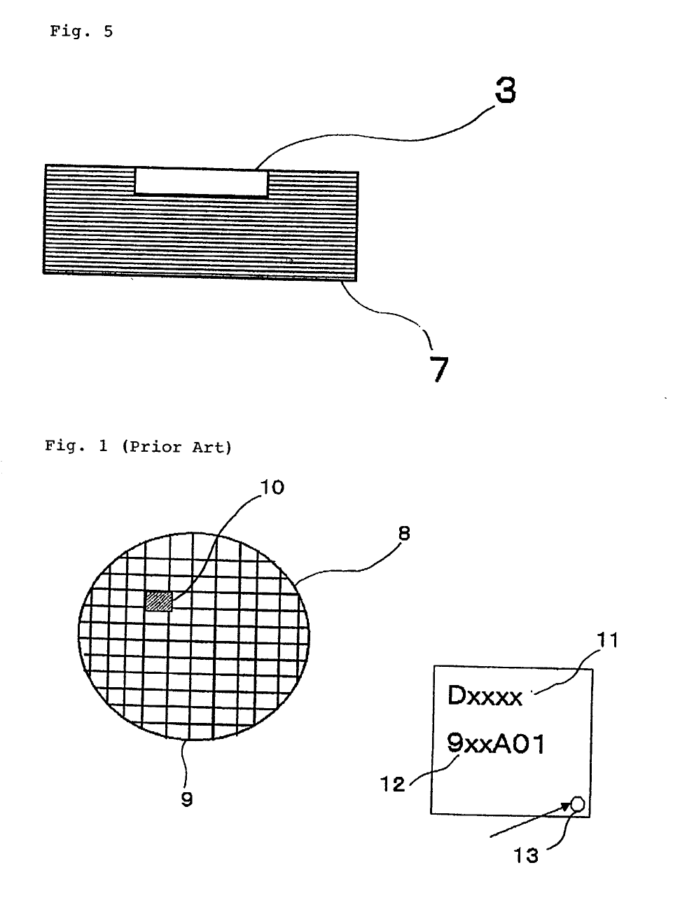

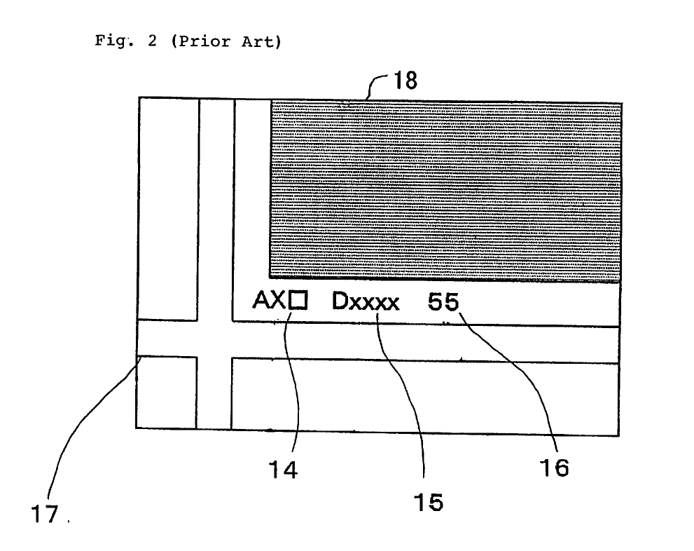

### DESCRIPTION OF PREFERRED EMBODIMENTS

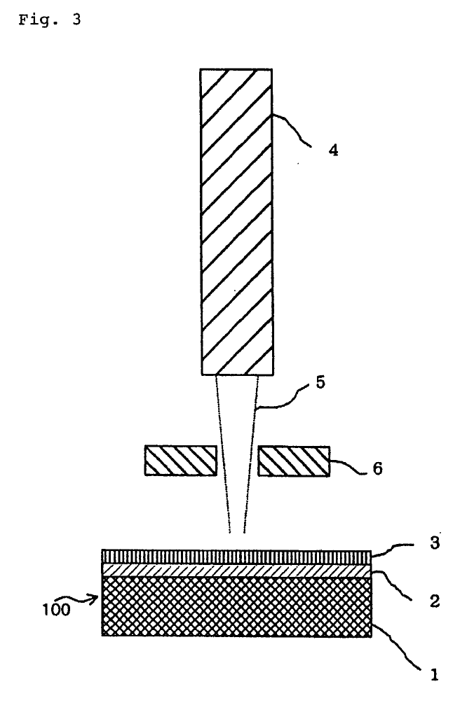

FIG. 3 shows a cross section of a semiconductor device according to an embodiment of the present invention and the constitution of a system for manufacturing a semiconductor device.

As shown in FIG. 3, in a semiconductor device 100 of the present embodiment, protective film 2 (made of polyimide) is formed on the surface of IC chip 1 which is the chip of a pattern formed wafer, over which high-molecular film 3 is formed. Aberchrome 540 or 850 is used as high-molecular film 3, the color of which is changed by irradiating the film with the laser beam of a wavelength range, 400 to 800 nm. In addition, since a PDA section should not be coated with high-molecular film 3, high-molecular film 3 is first applied after resist is applied, and resist is then exfoliated to make an opening at the PAD section.

In FIG. 3, the manufacturing system comprises a laser transmitter 4, which is capable of emitting laser beam 5 with the energy h ν where h is Planck's constant, ν is laser frequency, of a specific wavelength range to cause the color of high-molecular film 3 to change.

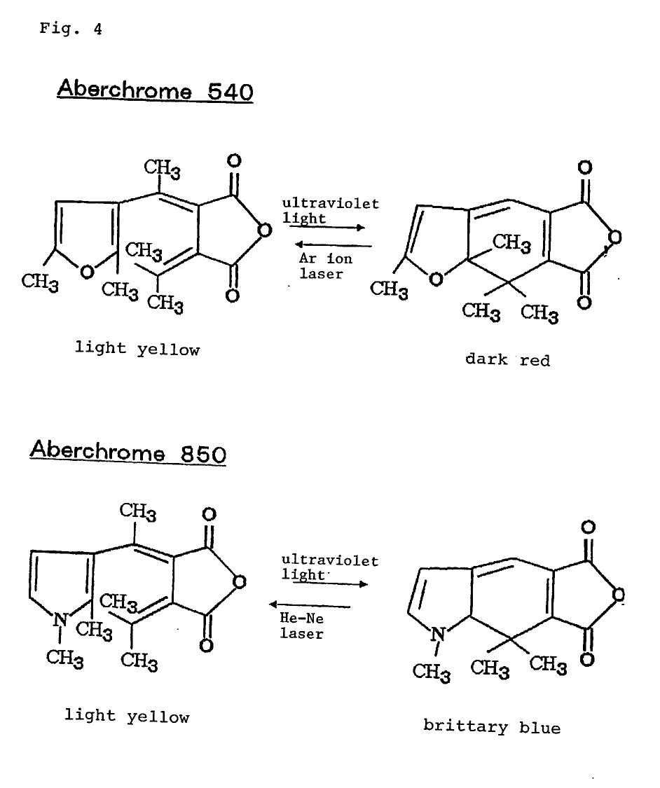

In this manufacturing system, an ultraviolet light or a blue light of wavelength range, 300 to 400 nm is first irradiated onto high-molecular film 3 to color high-molecular film 3. As shown in FIG. 4, if an ultraviolet light or a blue light is emitted, the color of the film is changed to dark red in case of Aberchrome 540 and it is changed to brittany blue in case of Aberchrome 850. Laser beam 5 with a wavelength range equivalent to a wavelength range to return to the original high-molecular structure is irradiated onto this colored surface. If Aberchrome 540 and 850 are used as high-molecular film 3, their absorption wavelength range is 400 to 800 nm. Examples of lasers in this wavelength range include Ar ion laser and He—Ne laser. High-molecular film 3 absorbs the energy h ν of laser beam 5 emitted to change its molecular structure, resulting in the change of the color of a film. As shown in FIG. 4, if Aberchrome 540 is used as high-molecular film 3, then the color is changed from dark red to light yellow when an argon ion laser beam is emitted and if Aberchrome 850 is used, the color is changed from brittany blue to light yellow when a helium ion laser beam is emitted.

Furthermore, since a wavelength range generating the dissociation of a molecular bond or the like constituting protective film 2 is shorter (248 nm of KrF laser or the like) than that of laser beam 5 for use in the manufacturing system of the embodiment, protective film 2 is not affected by laser beam 5.

Moreover, in the manufacturing system of the embodiment, slit 6 is provided between laser beam 5 and high-molecular film 3. It is possible to change the color of a film at an arbitrary point alone high-molecular film 3 by setting slit 6 at an arbitrary area out of the areas through which laser beam 5 passes and a bar code, a character, a numeric, symbol or the like can be formed on high-molecular film 3 by controlling a shape of slit 6 as desired. Consequently, the manufacturing system of the embodiment makes it possible to easily identify various marks visually in place of a method with a film color only and workability in experiments and evaluations can be improved. Also, as shown in FIG. 5, in addition to data writing at wafer probing test, writing of information at assembling is also possible by providing high-molecular film 3 in an arbitrary area on IC package 7 as well as IC chip 1.

As noted above, since the manufacturing system of the embodiment makes use of the feature that the film color of high-molecular film 3 is changed by emitting laser beam 5 of a specific wavelength range, IC chip 1 cannot be identified by either changing the layout in IC chip 1 or writing an itme of information on the back side of IC chip 1.

Also, the inventione provides the following advantages in identifying IC chip 1.

1) After confirming the electric characteristics at the time of P/w, the color of a high-molecular film is changed by irradiating the surface of a predetermined chip with a laser beam and for example, data on the identification of a high-speed derivative product and criteria of passing/rejection thereof can be recorded.

2) The change of a film color also makes it possible to easily identify a piece of information (P/W data or the like) in a previous process visually and easily recognize P/W condition at the time of pellet shipment.

3) Since the use of a laser beam for recording a piece of information on an IC chip can increase the resolution of a recorded item of information in place of ink that has been conventionally used, much more information can be marked on high-molecular film 3.

While preferred embodiments of the present invention have been described using specific terms, such description is for illustrative purposes only, and it is to be understood that changes and variations may be made without departing from the spirit of the following claims.

What is claimed is:

1. A semiconductor device comprising a pattern formed IC chip, and a high-molecular film formed on said IC chip, the color of said film being changed by radiating thereto with the light of a predetermined wavelength range.

2. The semiconductor device according to claim 1, wherein a protective film is formed between said IC chip and said high-molecular film, and a wavelength range dissociating a molecular bond constituting said protective film is shorter than said predetermined wavelength range.

3. A semiconductor device comprising an IC, an IC package, and a high-molecular film formed on said IC package, the color of said film being changed by irradiating thereto with the light of a predetermined wavelength range.

4. The semiconductor device according to claim 1, wherein said high-molecular film is made of Aberchrome 540.

5. The semiconductor device according to claim 1, wherein said high-molecular film is made of Aberchrome 850.

6. The semiconductor device according to claim 3, wherein said high-molecular film is made of Aberchrome 540.

7. The semiconductor device according to claim 3, wherein said high-molecular film is made of Aberchrome 850.

8. A method of identifying a plurality of IC chips obtained from a pattern formed wafer, the method comprising the steps of:
forming a high-molecular film on the surface of an IC chip, the color of said film being changed by irradiating said film with a predetermined wavelength range,
recording an item of information on each of said IC chips by irradiating the surface of said IC chip with the light of a predetermined wavelength range, and
identifying each of said IC chips based on an in item of information recorded on said high-molecular film.

9. A system for manufacturing a semiconductor device comprising, means for forming a high-molecular film on the surface of an IC chip, the color of said film being changed by irradiating said film with the light of a predetermined wavelength range, and light irradiating means for irradiating said IC chip.

10. The manufacturing system according to claim 9, wherein a slit is interposed between said light irradiating means and said semiconductor device to limit the area of a light reaching said IC chip to a predetermined shape.
